(19) United States
(12) Patent Application Publication
(10) Pub. No.: US 2024/0258217 A1
(43) Pub. Date: Aug. 1, 2024

(54) SEMICONDUCTOR DEVICE PACKAGES INCLUDING MULTILAYER STACKS WITH IMPROVED ADHESION

(71) Applicant: Wolfspeed, Inc., Durham, NC (US)

(72) Inventors: Afshin Dadvand, Durham, NC (US); Devarajan Balaraman, Apex, NC (US)

(21) Appl. No.: 18/161,144

(22) Filed: Jan. 30, 2023

(51) Int. Cl. H01L 23/495; H01L 21/48; H01L 23/00

(52) U.S. Cl. CPC H01L 23/49582; H01L 21/4821; H01L 23/49513; H01L 24/05; H01L 24/29; H01L 24/32; H01L 23/293; H01L 23/296; H01L 24/48; H01L 24/73; H01L 2224/05073; H01L 2224/05082; H01L 2224/05155; H01L 2224/05157; H01L 2224/05166; H01L 2224/05171; H01L 2224/0518; H01L 2224/05573; H01L 2224/05639; H01L 2224/05644; H01L 2224/29111; H01L 2224/29139; H01L 2224/32245; H01L 2224/48091; H01L 2224/48105; H01L 2224/48175; H01L 2224/73265; H01L 2924/10272

(57) ABSTRACT

A semiconductor device package includes a conductive submount, a metal layer comprising a first material on the conductive submount, and at least one conductive buffer layer comprising a second material on the metal layer. The conductive buffer layer may be between the metal layer and the conductive submount, or may be between the metal layer and a transistor die on the conductive submount. The second material of the conductive buffer layer has limited or no solid solubility with respect to the first material of the metal layer. Related packages and fabrication techniques are also discussed.

### FIELD

The present invention relates to semiconductor devices, and more particularly, to semiconductor device packages and related fabrication methods.

### BACKGROUND

Power semiconductor devices refer to devices that include one or more semiconductor die that are designed to carry large currents (e.g., tens or hundreds of Amps) and/or that are capable of blocking high voltages (e.g., hundreds, thousand or tens of thousands of volts). A wide variety of power semiconductor devices are known in the art including, for example, power Metal Insulator Semiconductor Field Effect Transistors (“MISFETs”, including Metal Oxide Semiconductor FETs (“MOSFETs”)), bipolar junction transistors (“BJTs”), Insulated Gate Bipolar Transistors (“IGBT”), Junction Barrier Schottky diodes, Gate Turn-Off Transistors (“GTO”), MOS-controlled thyristors, and various other devices. These power semiconductor devices are generally fabricated from wide bandgap semiconductor materials, for example, silicon carbide (“SiC”) or Group III nitride (e.g., gallium nitride (“GaN”))-based semiconductor materials. Herein, a wide bandgap semiconductor material refers to a semiconductor material having a bandgap greater than about 1.40 eV, for example, greater than about 2 eV.

A conventional power semiconductor device typically has a semiconductor substrate having a first conductivity type (e.g., an n-type substrate) on which an epitaxial layer structure having the first conductivity type (e.g., n-type) is formed. A portion of this epitaxial layer structure (which may comprise one or more separate layers) functions as a drift layer or drift region of the power semiconductor device. The device typically includes an “active region,” which includes one or more “unit cell” structures that have a junction, for example, a p-n junction. The active region may be formed on and/or in the drift region. The active region acts as a main junction for blocking voltage in the reverse bias direction and providing current flow in the forward bias direction. The power semiconductor device may also have an edge termination in a termination region that is adjacent the active region. One or more power semiconductor devices may be formed on the substrate, and each power semiconductor device will typically have its own edge termination.

Power semiconductor devices may have configurations in which a large number of individual unit cell structures of the active region are electrically connected (e.g., in parallel) to function as a single power semiconductor device. In high power applications, such a power semiconductor device may include thousands or tens of thousands of unit cells implemented in a single chip or “die.” A die or chip may include a small block of semiconducting material or other substrate in which electronic circuit elements are fabricated. For example, a plurality of individual power semiconductor devices may be formed on a relatively large semiconductor substrate (e.g., by growing epitaxial layers thereon, doping selected regions with dopants, forming insulation and metal layers thereon, etc.). After the substrate is fully processed, the resultant structure may then be cut (e.g., by a sawing, lasering, or dicing operation) to separate the individual edge-terminated power semiconductor devices into a plurality of individual die, each of which is a power semiconductor device.

Power semiconductor devices may be integrated into packages including semiconductor die(s), input and output leads, and a housing or other protective member (e.g., a lid member for open-cavity packages or a mold structure, such as epoxy molding compound (EMC), for overmold packages). Semiconductor device packaging is continuously moving towards smaller form factors. However, complexities may arise due to dissimilar materials used in the die, die attach, metal lead frame, metal wires, and protective coverings, some of which may have dissimilar thermo-mechanical properties, such as different coefficients of thermal expansion (CTE). This mismatch between the material properties can exert high stresses in the package, for example, cyclic fatigue during temperature excursions, making it susceptible to interfacial delamination and cracking.

### SUMMARY

According to some embodiments of the present disclosure, a semiconductor device package includes a conductive submount; a metal layer comprising a first material on the conductive submount; and a conductive buffer layer comprising a second material on the metal layer. The second material of the conductive buffer layer has limited or no solid solubility with respect to the first material of the metal layer.

In some embodiments, the conductive buffer layer is provided between the metal layer and the conductive submount, and the semiconductor device package is free of an intermetallic compound comprising the first material between the metal layer and the conductive submount.

In some embodiments, the semiconductor device package includes an intermetallic compound comprising the second material between the conductive buffer layer and the conductive submount.

In some embodiments, the first material comprises a noble metal or alloy thereof, and the second material comprises at least one of nickel, cobalt, molybdenum, chromium, titanium, or alloys thereof.

In some embodiments, the metal layer comprises a lower bonding interface with the conductive buffer layer and an upper bonding interface opposite the lower bonding interface. A first interfacial stress at the upper bonding interface is substantially similar to a second interfacial stress at the lower bonding interface.

In some embodiments, a bonding strength at the lower bonding interface is less than a bonding strength of a direct bonding interface between the metal layer and the conductive submount.

In some embodiments, a mold structure is provided on the metal layer opposite the conductive submount, and the upper bonding interface is between the metal layer and the mold structure.

In some embodiments, the mold structure comprises at least one of epoxy, silicone, or bismaleimide.

In some embodiments, the metal layer is a first metal layer, and the semiconductor device package further includes a die attach material on the first metal layer opposite the conductive submount; and a second metal layer on the die attach material. A third interfacial stress at a bonding interface between the first metal layer and the die attach material is substantially similar to a fourth interfacial stress at a bonding interface between the second metal layer and the die attach material.

In some embodiments, the conductive buffer layer is a first conductive buffer layer, and the semiconductor device package further includes a transistor die on the die attach material opposite the first metal layer; and a second conductive buffer layer between the transistor die and the second metal layer. The second conductive buffer layer and the second metal layer comprise a back metal layer of the transistor die, and a fifth interfacial stress at a bonding interface between the second metal layer and the second conductive buffer layer is substantially similar to the second interfacial stress at the lower bonding interface between the first metal layer and the first conductive buffer.

In some embodiments, the conductive submount comprises copper, iron, or alloys thereof.

In some embodiments, the conductive buffer layer has a thickness of about 0.1 microns to about 5 microns, or about 0.2 microns to about 1 micron.

In some embodiments, the conductive buffer layer comprises a multi-layer structure including a plurality of alternating sublayers having respective thicknesses of about 0.1 microns to about 1 micron.

According to some embodiments, a semiconductor device package includes a conductive submount; and a metal layer comprising a first material on the conductive submount. The semiconductor device package is free of an intermetallic compound comprising the first material between the metal layer and the conductive submount.

In some embodiments, a conductive buffer layer comprising a second material is provided between the conductive submount and the metal layer. The second material has limited or no solid solubility with respect to the first material.

In some embodiments, the semiconductor device package includes an intermetallic compound comprising the second material between the conductive buffer layer and the conductive submount.

In some embodiments, the first material comprises a noble metal or alloy thereof, and the second material comprises at least one of nickel, cobalt, molybdenum, chromium, titanium, or alloys thereof.

In some embodiments, the metal layer comprises a lower bonding interface adjacent the conductive submount and an upper bonding interface opposite the lower bonding interface, and a first interfacial stress at the upper bonding interface is substantially similar to a second interfacial stress at the lower bonding interface.

In some embodiments, a mold structure is provided on the metal layer opposite the conductive submount, and the upper bonding interface is between the metal layer and the mold structure.

In some embodiments, a bonding strength at the lower bonding interface is less than a bonding strength of a direct bonding interface between the metal layer and the conductive submount.

According to some embodiments, a semiconductor device package includes a conductive submount; and a conductive layer stack comprising a metal layer on the conductive submount, the metal layer comprising a lower bonding interface adjacent the conductive submount and an upper bonding interface opposite the lower bonding interface. A first interfacial stress at the upper bonding interface is substantially similar to a second interfacial stress at the lower bonding interface.

In some embodiments, a bonding strength at the lower bonding interface is less than a bonding strength of a direct bonding interface between the metal layer and the conductive submount.

In some embodiments, the metal layer comprises a first material, and the conductive layer stack further includes a conductive buffer layer comprising a second material on the metal layer, where the second material has limited or no solid solubility with respect to the first material.

In some embodiments, the semiconductor device package is free of an intermetallic compound comprising the first material between the metal layer and the conductive submount.

In some embodiments, an intermetallic compound comprising the second material is provided between the conductive buffer layer and the conductive submount.

In some embodiments, the first material comprises a noble metal or alloy thereof, and the second material comprises at least one of nickel, cobalt, molybdenum, chromium, titanium, or alloys thereof.

In some embodiments, a mold structure is provided on the metal layer opposite the conductive submount, and the upper bonding interface is between the metal layer and the mold structure.

In some embodiments, the metal layer is a first metal layer, and the semiconductor device package further includes a die attach material on the first metal layer opposite the conductive submount; and a second metal layer on the die attach material. A third interfacial stress at a bonding interface between the first metal layer and the die attach material is substantially similar to a fourth interfacial stress at a bonding interface between the second metal layer and the die attach material.

In some embodiments, the conductive buffer layer is a first conductive buffer layer, the semiconductor device package further includes a transistor die on the die attach material opposite the first metal layer; and a second conductive buffer layer between the transistor die and the second metal layer. The second conductive buffer layer and the second metal layer comprise a back metal layer of the transistor die, and a fifth interfacial stress at a bonding interface between the second metal layer and the second conductive buffer layer is substantially similar to the second interfacial stress at the lower bonding interface of the first metal layer and the first conductive buffer.

According to some embodiments, a semiconductor device package includes a conductive submount; and a metal layer on the conductive submount, the metal layer comprising a lower bonding interface adjacent the conductive submount. A bonding strength at the lower bonding interface is less than a bonding strength of a direct bonding interface between the metal layer and the conductive submount.

In some embodiments, the metal layer comprises an upper bonding interface opposite the lower bonding interface, and a first interfacial stress at the upper bonding interface is substantially similar to a second interfacial stress at the lower bonding interface.

In some embodiments, the metal layer comprises a first material, and a conductive buffer layer comprising a second material is provided between the conductive submount and the metal layer, where the second material has limited or no solid solubility with respect to the first material.

In some embodiments, the semiconductor device package further includes an intermetallic compound comprising the second material between the conductive buffer layer and the conductive submount.

In some embodiments, the first material comprises a noble metal or alloy thereof, and the second material comprises at least one of nickel, cobalt, molybdenum, chromium, titanium, or alloys thereof.

In some embodiments, a mold structure is provided on the metal layer opposite the conductive submount, and the upper bonding interface is between the metal layer and the mold structure.

According to some embodiments, a method of fabricating a semiconductor device package includes providing a conductive submount; and forming a metal layer comprising a first material on the conductive submount and free of an intermetallic compound comprising the first material between the metal layer and the conductive submount.

In some embodiments, forming the metal layer comprises forming a conductive buffer layer on the conductive submount; and forming the metal layer on the conductive buffer layer. The conductive buffer layer comprises a second material that has limited or no solid solubility with respect to the first material.

In some embodiments, an intermetallic compound comprising the second material is formed between the conductive buffer layer and the conductive submount.

In some embodiments, the first material comprises a noble metal or alloy thereof, and the second material comprises at least one of nickel, cobalt, molybdenum, chromium, titanium, or alloys thereof.

In some embodiments, the metal layer comprises a lower bonding interface with the buffer layer and an upper bonding interface opposite the lower bonding interface, and a first interfacial stress at the upper bonding interface is substantially similar to a second interfacial stress at the lower bonding interface.

In some embodiments, a bonding strength at the lower bonding interface is less than a bonding strength of a direct bonding interface between the metal layer and the conductive submount.

In some embodiments, a mold structure is formed on the metal layer opposite the conductive submount, where the upper bonding interface is between the metal layer and the mold structure.

In some embodiments, the metal layer is a first metal layer, and the method further comprises: providing a die attach material on the first metal layer opposite the conductive submount; and providing a transistor die on the die attach material opposite the first metal layer, wherein the transistor die comprises a back metal layer comprising a second metal layer that is between a semiconductor material of the transistor die and the die attach material. A third interfacial stress at a bonding interface between the first metal layer and the die attach material is substantially similar to a fourth interfacial stress at a bonding interface between the second metal layer and the die attach material.

In some embodiments, the conductive buffer layer is a first conductive buffer layer, and the back metal layer comprises a second conductive buffer layer between the semiconductor material and the second metal layer. A fifth interfacial stress at a bonding interface between the second metal layer and the second conductive buffer layer is substantially similar to the second interfacial stress at the lower bonding interface of the first metal layer and the first conductive buffer.

According to some embodiments, a semiconductor device package includes a conductive submount; a transistor die on the conductive submount; and a conductive layer stack between the transistor die and the conductive submount. The conductive layer stack comprises a die attach material, at least one metal layer comprising a first material, and at least one conductive buffer layer comprising a second material having limited or no solid solubility with respect to the first material.

In some embodiments, the at least one metal layer comprises a first metal layer that provides one or more die pads and/or one or more wire bond pads on the conductive submount, and the at least one conductive buffer layer comprises a first conductive buffer layer between the first metal layer and the conductive submount.

In some embodiments, the at least one metal layer comprises a second metal layer, and the at least one conductive buffer layer comprises a second conductive buffer layer between the second metal layer and a surface of the transistor die.

In some embodiments, a mold structure is provided on the first metal layer opposite the conductive submount. A first interfacial stress at a bonding interface between the first metal layer and the mold structure is substantially similar to a second interfacial stress at a bonding interface between the first metal layer and the first conductive buffer layer.

In some embodiments, a third interfacial stress at a bonding interface between the first metal layer and the die attach material is substantially similar to a fourth interfacial stress at a bonding interface between the second metal layer and the die attach material.

In some embodiments, a fifth interfacial stress at a bonding interface between the second metal layer and the second conductive buffer layer is substantially similar to the second interfacial stress at the bonding interface between the first metal layer and the first conductive buffer layer.

Other devices, apparatus, and/or methods according to some embodiments will become apparent to one with skill in the art upon review of the following drawings and detailed description. It is intended that all such additional embodiments, in addition to any and all combinations of the above embodiments, be included within this description, be within the scope of the invention, and be protected by the accompanying claims.

### BRIEF DESCRIPTION OF THE DRAWINGS

FIG. 1 is a schematic cross-sectional view of an example semiconductor device package including one or more conductive buffer layers according to some embodiments of the present disclosure.

FIG. 2 is an enlarged schematic cross-sectional view of portion II-II of the semiconductor device package of FIG. 1 according to some embodiments of the present disclosure.

FIG. 3 is an enlarged schematic cross-sectional view of portion III-III of the semiconductor device package of FIG. 1 according to some embodiments of the present disclosure.

FIG. 4A is an enlarged schematic cross-sectional view illustrating interfaces between layers in a semiconductor device package including one or more conductive buffer layers according to some embodiments of the present disclosure.

FIG. 4B is an enlarged schematic cross-sectional view illustrating interfaces between layers in a semiconductor device package including one or more conductive buffer layers according to some embodiments of the present disclosure.

FIG. 5 is a schematic cross-sectional view of an example semiconductor device package including a conductive layer stack with multiple buffer layers according to some embodiments of the present disclosure.

FIG. 6 is an enlarged schematic cross-sectional view of portion VI-VI of the semiconductor device package of FIG. 5 according to some embodiments of the present disclosure.

FIGS. 7A and 7B are flowcharts illustrating example operations for fabricating a semiconductor device package according to some embodiments of the present disclosure.

FIG. 8 is a schematic cross-sectional view of an example semiconductor device package according to a comparative example.

FIG. 9 is an enlarged schematic cross-sectional view of portion IX-IX of the semiconductor device package of FIG. 8 according to a comparative example.

FIG. 10 is an enlarged cross-sectional view of portion X-X of the semiconductor device package of FIG. 8 according to a comparative example.

### DETAILED DESCRIPTION OF EMBODIMENTS

Leadframe based packages, such as quad flat packages (QFP) and quad flat no lead (QFN) packages, may be used for many semiconductor packages. Copper (Cu) wirebonding has gained attention in the industry over gold (Au) bonding due to its lower cost. Metal (e.g., silver) plating may typically be applied to a Cu leadframe to provide a metal bond pad that is configured for Cu wirebonding. However, adhesion of the mold compound material to metal plated leadframes may be significantly lower than adhesion to bare copper leadframes. Adhesion between silver (Ag) wire-bonding pads on Cu leadframes and mold compound (MC) may be achieved through mechanical anchoring (physisorption) plus partial chemisorption, which may not provide adequate adhesion strength, particularly with larger bond pad areas. Similarly, Ag-plated Cu leadframes may suffer from low interfacial adhesion.

Due to these differences in adhesion, delamination at the mold compound and metal plating interface (e.g. at the interface between the mold compound and portions of a die pad and/or a wire bond pad) may be a common failure mode observed during processing and qualification of semiconductor device packages. For example, the contact area between the mold compound and the die pad may have a relatively large shear stress among the various interfaces between the different materials of a semiconductor device package. Delamination may typically be observed after environmental reliability stresses, such as moisture preconditioning and reflow, air-to-air thermal cycling, or biased highly accelerated stress etc. Any delamination at the mold compound-metal plating interface can propagate under the bonding interface or exert more stress on the bonding interface, creating cracks or lift-offs, and subsequent failure of the packaged device.

Some embodiments of the present invention may arise from efforts to identify causes and mechanisms of failure (in particular, delamination) between metal layers (e.g., wire bond pads or die pads, including metal plated layers) on conductive submounts (e.g., lead frames or other conductive leads) and mold structures (e.g., formed from a molding compound, such as EMC). Embodiments described herein may avoid or significantly mitigate such failure or delamination at an upper interface of the metal layer (e.g., between the metal layer and the mold structure), for example, through deposition of one or more conductive buffer layers between the metal layer and the conductive submount or lead, which may significantly improve reliability of power discrete packages or power modules.

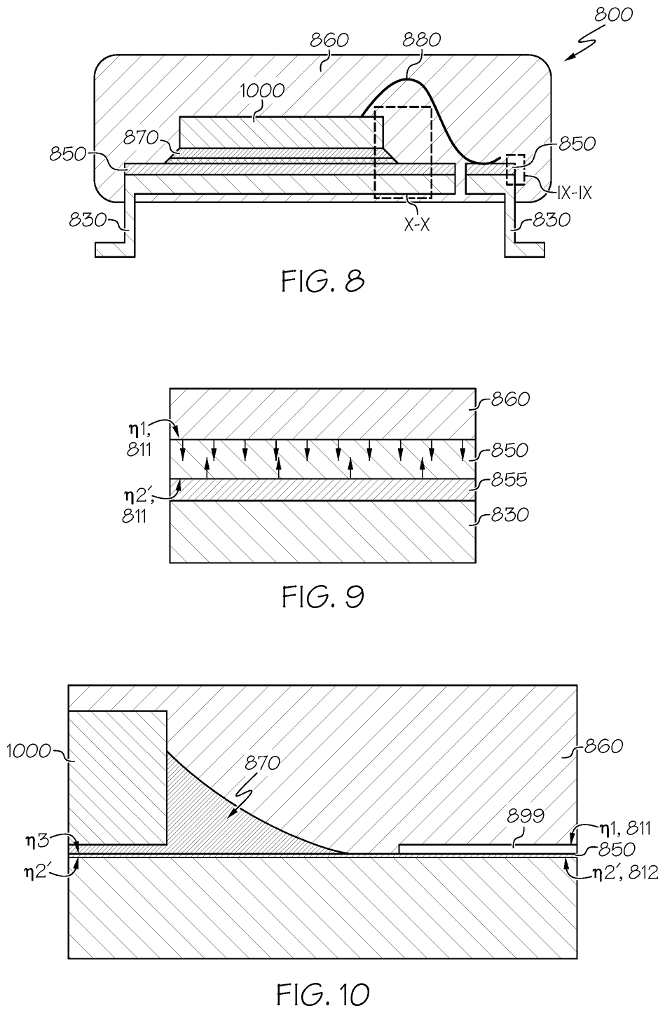

FIGS. 8, 9, and 10 illustrate delamination between a silver(Ag)-plated copper (Cu) submount and an EMC in comparative structures. In particular, FIG. 8 is a schematic cross-sectional view of an example semiconductor device package 800 according to a comparative example, FIG. 9 is an enlarged schematic cross-sectional view of portion IX-IX of the semiconductor device package 800 of FIG. 8, and FIG. 10 is an enlarged cross-sectional view of portion X-X of the semiconductor device package 800 of FIG. 8.

The package 800 of FIG. 8 includes a semiconductor die 1000 mounted on a conductive submount 830, such as a conductive leadframe, and protected by an EMC or other mold compound 860. The submount 830 includes an Ag-plated metal layer 850 that provides one or more bonding surfaces (e.g., a die attach pad, on which a die attach material 870 is provided, and a wire bond pad, to which a wire bond 880 is attached). However, as noted above, adhesion between the metal layer 850 and the mold compound 860 may be relatively weak.

In particular, as shown in FIGS. 9 and 10, a bond with a relatively low bonding strength η1 (also referred to herein as adhesion strength) may be formed at an upper bonding interface 811 between the Ag metal layer 850 and the mold compound 860. On the other hand, a lower bonding interface 812 between the Cu submount 830 and the Ag metal layer 850 may have a relatively high bonding strength η2′ (for example, due to Cu—Ag interdiffusion, resulting in formation of an Ag-containing intermetallic compound 855), such that η1<η2′. This unevenness of bonding strengths η1, η2′ at opposing interfaces 811, 812 of the Ag metal layer 850 may result in a higher level of stress at the upper bonding interface 811 (e.g., the Ag-MC interface), as illustrated by the arrows in FIG. 9. In general, the larger the difference between the bonding strengths η1 and η2′, the weaker the adhesion of the metal layer to the molding structure. Moisture absorption may also degrade adhesion strength, while mismatch in coefficients of thermal expansion (CTE) between the dissimilar materials may exert interfacial stress. If the interfacial stress is larger than the adhesion strength, delamination may occur. In particular, FIG. 10 illustrates delamination 899 along the bonding interface 811 between the Ag metal layer 850 and the mold compound 860.

Some conventional methods for reducing the risk of delamination may include increasing the adhesion strength between the mold structure and the metal layer, reducing moisture absorption, and including mechanical features in the metal layer (e.g., grooves, locking holes) to enhance interaction at the interface between the mold structure and the metal layer. That is, some conventional techniques may be directed to preventing delamination by increasing the bonding strength at the interface where delamination typically occurs (i.e., at the upper bonding interface between the mold structure and the metal layer).

In contrast, embodiments of the present disclosure are directed to preventing delamination by addressing imbalances in stress at the opposing upper and lower bonding interfaces of one or more metal layers in a conductive layer stack. In particular, some embodiments of the present disclosure may improve adhesion by altering the adhesion strength at the upper and/or lower bonding interfaces of a metal layer. For example, some embodiments may provide one or more conductive buffer layers between the metal layer and a conductive submount or lead, to thereby reduce differences in (e.g., balance) interfacial stresses at the upper and lower bonding interfaces of the metal layer.

In some embodiments, the material(s) of the conductive buffer layer(s) may be selected such that the bonding strength at the lower bonding interface between the metal layer and the buffer layer is weaker than a direct bond between the metal layer and the conductive submount or lead. For example, the material(s) of the conductive buffer layer may be selected to prevent formation of an intermetallic compound including material(s) of the metal layer (e.g., to prevent formation of the Cu—Ag intermetallic compound shown in FIG. 9), which would otherwise provide a high-strength bond. As such, adhesion strength may be reduced in comparison to a direct bond between the metal layer and the conductive submount or lead, which may be counterintuitive in comparison to some conventional methods of improving adhesion by increasing adhesion strength.

In some embodiments, a metal layer and a conductive buffer layer may be implemented as backside metallization of a transistor die. Additional conductive buffer layer(s) and/or metal layers may be provided between the conductive submount and a transistor die (e.g., a SiC die), to provide a conductive layer stack that is configured to reduce and/or minimize imbalances in stress between opposing upper and lower surfaces of one or more of the metal layers in the conductive layer stack.

In some embodiments, the conductive buffer layer may be a thin-layer (e.g., having a thickness of about 0.1 μm to 5 μm, for example about 0.2 μm to 1 μm) of nickel (Ni), cobalt (Co), or molybdenum (Mo), which may be coated (e.g., through electrodeposition or electroless process) on a conductive submount (e.g., a Cu-based leadframe) before a metal (e.g., Ag) layer is formed on the conductive submount (e.g., to provide die attach and/or wire bonding pads). The conductive buffer layer is configured to reduce differences between or balance out the interfacial bond strengths at the upper and lower bonding interfaces of the metal layer, which can prevent or significantly mitigate the risk of delamination of the mold structure. The conductive buffer layer(s) may be formed of Ni, Co, Mo, and/or other materials having a very low solid solubility with respect to the material (e.g., Ag) of the metal layer, such that formation of an intermetallic compound containing the material of the metal layer may be reduced or avoided. In some embodiments, due to the lack of miscibility, respective bonding strengths of Ag—Ni, Ag—Co, and/or Ag—Mo solute-solvent bonds may be expected to be very weak compared to the bonding strength at a direct Ag—Cu bonding interface (i.e., a direct bonding interface between the metal layer and the conductive submount), thus balancing the stress imposed on both the upper and lower bonding interfaces of the Ag metal layer. This can prevent or significantly reduce the risk of delamination at the Ag-mold structure interface during device operation or during different reliability verifications.

More generally, embodiments of the present disclosure are directed to reducing differences in interfacial stresses at upper and lower bonding interfaces of respective metal layers in a conductive layer stack, for example, by reducing differences in respective bonding strengths n at the various interfaces between dissimilar materials of the conductive layer stack. Some embodiments may include combinations of material layers and layer thicknesses that achieve substantially similar interfacial stresses (e.g., by providing similar bonding strengths) at upper and lower bonding interfaces of one or more metal layers in a conductive layer stack. Embodiments of the present disclosure may thereby reduce or avoid delamination of the mold structure and a metal layer on a conductive submount (for example between EMC and Ag bond pads on a Cu leadframe) due to low interfacial adhesion strength, CTE mismatch, and/or other interfacial stress imbalances.

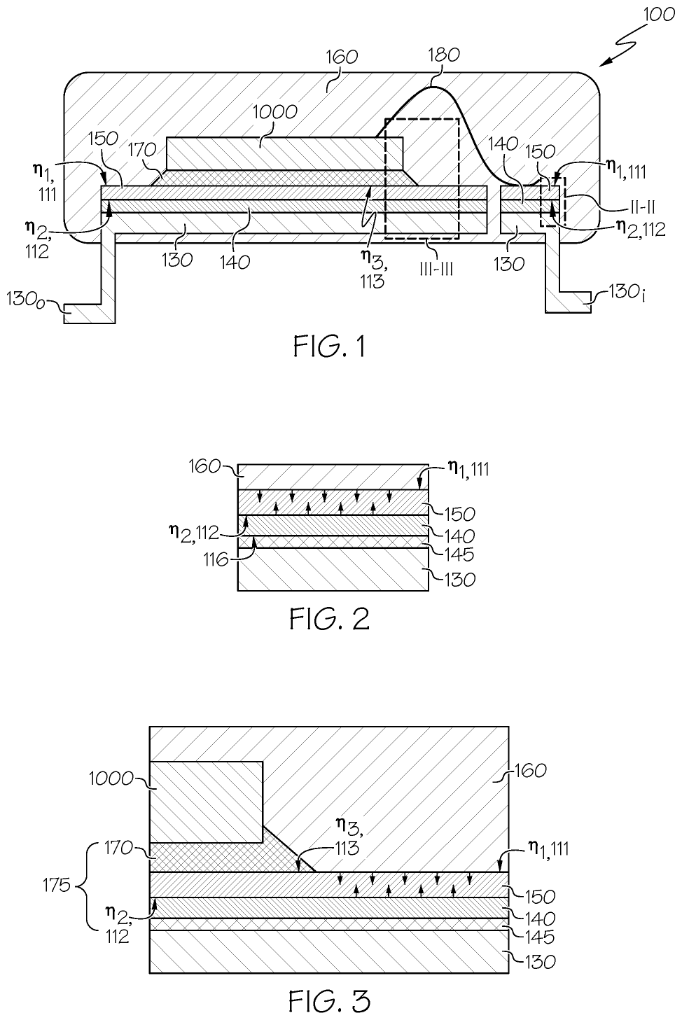

FIG. 1 is a schematic cross-sectional view of an example semiconductor device package 100 including one or more conductive buffer layers 140 according to some embodiments of the present disclosure. FIGS. 2 and 3 are enlarged schematic cross-sectional views of portions II-II and III-III of the semiconductor device package 100 of FIG. 1, respectively.

As shown in FIGS. 1 to 3, a semiconductor device package 100 includes a conductive submount 130 and a metal layer 150 on the conductive submount 130. The conductive submount 130 may provide a leadframe and/or one or more conductive leads (for example, an input lead and an output lead) of the semiconductor package. The metal layer 150 may be formed on the conductive submount 130, for example, using a plating or other deposition process. The metal layer 150 may provide one or more die pads and/or one or more wire bond pads on the conductive sub mount. One or more wires or wire bonds 180 may be provided on the wire bond pads provided by the metal layer 150. A die attach material 170 may be provided on the die pad provided by the metal layer 150, and a semiconductor transistor die 1000 may be provided on the die attach material 170 opposite the metal layer 150. The transistor die 1000 (e.g., a SiC die) may include an input terminal coupled to the input lead 130i (e.g., by a wire bond 180), and an output terminal coupled to the output lead 1300 (e.g., by a conductive layer stack 175). A mold structure 160 (e.g., epoxy, silicone, bismaleimide, or other mold compound) may be formed on the metal layer 150 opposite the conductive submount 130 to complete the semiconductor device package 100.

The metal layer 150 may be formed of a first material (e.g. silver, gold, or alloys thereof), which is different from the material of the conductive submount 130 (e.g., copper, iron, or alloys thereof). In some embodiments, the first material of the metal layer 150 may have a high solid solubility with the material of the conductive surmount, such that an intermetallic compound (e.g., 855 in FIG. 9) including the first material may be formed at a direct bonding interface between the metal layer 150 and the conductive sub mount. For example, the first material of the metal layer 150 may include silver, and the conductive sub mount may include copper, such that (as shown in the comparative example of FIG. 9) a Cu—Ag intermetallic compound 855 (with a high bonding strength η2′) may be formed at a direct bonding interface between the metal layer 850 and the conductive submount 830, which may result in a stress imbalance between upper and lower bonding surfaces of the metal layer 850 (e.g., with a different interfacial stress between the mold structure 860 and the metal layer 850 versus between the metal layer 850 and the conductive submount 830.

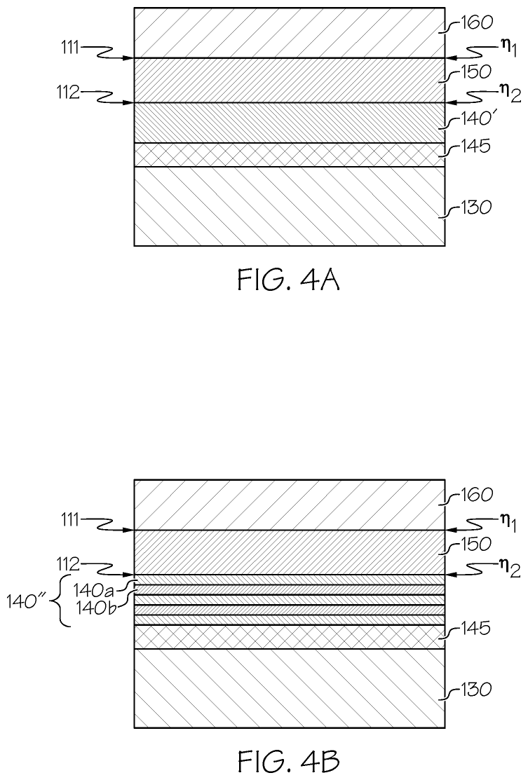

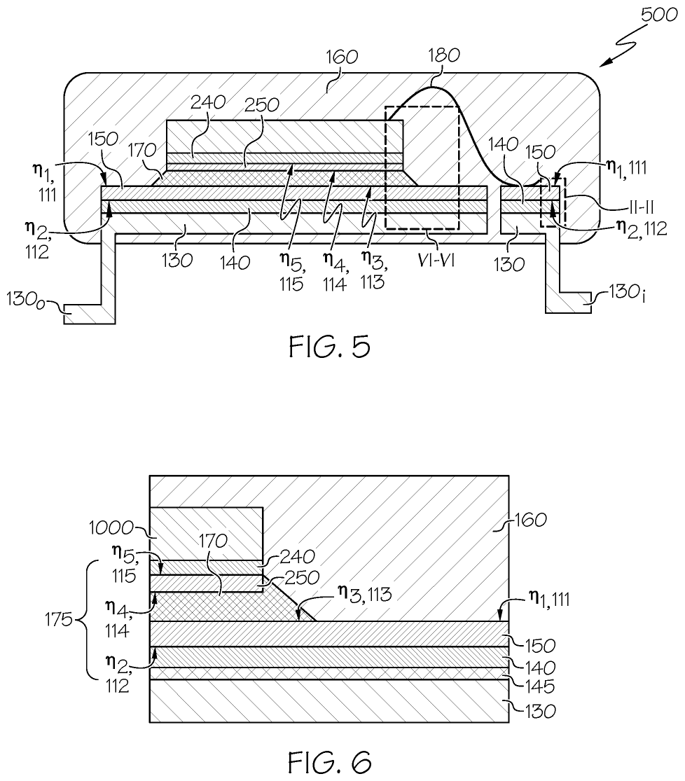

In the examples of FIGS. 1 to 3, the semiconductor device package 100 further includes a conductive buffer layer 140 on the metal layer 150. The conductive buffer layer 140 is provided between the metal layer 150 and the conductive submount 130, such that the metal layer 150 may have a lower bonding interface 112 with the conductive buffer layer 140, and an upper bonding interface 111 (e.g., with the mold structure 160) opposite the lower bonding interface 112. Additional conductive buffer layers may also be provided (for example, in a multi-layer stack 140″ as shown in FIG. 4B, and/or as part of the backside metallization 350 of the transistor die 1000 as shown in FIGS. 5 and 6) in some embodiments, all of which may be included in or provide the conductive layer stack 175 as described herein.

The conductive buffer layer 140 may be formed of a second material, which is different from the first material of the metal layer 150. For example, the first material of the metal layer 150 may be a noble metal or alloy thereof, while the second material of the conductive buffer layer 140 may include nickel, cobalt, molybdenum, chromium, titanium, and/or alloys thereof. The second material may be selected to have limited or no solid solubility with respect to the first material of the metal layer 150, such that the semiconductor package may be free of an intermetallic compound 855 including the first material between the metal layer 150 and the conductive submount 130. Rather, an intermetallic compound 145 including the second material may be provided between the conductive buffer layer 140 and the conductive submount 130 (e.g., a Cu—Ni layer). As such, an adhesion strength or bonding strength η2 at the lower bonding interface 112 of the metal layer 150 is less than (i.e., weaker than) a bonding strength of a direct bonding interface between the metal layer 150 and the conductive submount 130 (e.g., the bonding strength η2′ shown in FIG. 9).

As shown in FIGS. 2 and 3, the conductive buffer layer 140 is configured to provide a bond with a relatively low bonding strength η2 at the lower bonding interface 112 with the metal layer 150, which may be substantially similar to the relatively low bonding strength η1 at the upper bonding interface 111 between the metal layer 150 and the mold structure 160 (i.e., η1≈η2). By reducing or balancing the differences between the bonding strengths η1, η2 at the upper 111 and lower 112 bonding interfaces of the metal layer 150, interfacial stresses at the respective bonding interfaces may be reduced, such that a first interfacial stress at the upper bonding interface 111 may be substantially similar to a second interfacial stress at the lower bonding interface 112, as shown by the arrows along the respective bonding interfaces in FIGS. 2 and 3. More generally, the smaller the difference between the bonding strengths η1 and η2, the greater the adhesion of the molding structure to the metal layer 150.

As shown in FIG. 3, while substantially similar bonding strengths η1, η2 (and thus, substantially similar interfacial stresses) may be achieved at the upper and lower bonding interfaces 111, 112 of portions of the metal layer 150 that are free of the die attach material 170, the bonding interface 113 between the metal layer 150 and the die attach material 170 may have a bonding strength η3 that is different (e.g., greater) than the bonding strength η2 at the bonding interface 112 between the metal layer 150 and the conductive buffer layer 140 (e.g., η3>η2), which may introduce challenges with respect to stress imbalances in the conductive layer stack 175 (which, in the example of FIG. 3, may include the die attach material 170, the metal layer 150, and the conductive buffer layer 140). Possible intermetallic compound formation (e.g., when using solder (which may be Sn-based) as the die attach material 170, or Ag—Ag interdiffusion when using Ag as the die attach material 170), may result in the greater bonding strength η3. In some embodiments, the conductive buffer layer 140 may be formed of NiW or NiV (instead of Ni) to aid in reducing this additional stress imbalance.

FIGS. 4A and 4B are enlarged schematic cross-sectional views illustrating interfaces between layers in a semiconductor device package 100 including one or more conductive buffer layers 140 according to some embodiments of the present disclosure.

As shown in FIGS. 4A and 4B, the conductive buffer layer 140 may be implemented an alloy 140′ (in FIG. 4A) or a multi-layer structure 140″ (in FIG. 4B) including a second material having limited or no solid solubility with the first material of the metal layer 150. As used herein, “limited solid solubility” or “limited miscibility” may refer to a solid solubility or miscibility of less than about 2 percent, for example, less than about 1 percent, while “no solid solubility” or “immiscibility” may refer to insolubility, or a very small solid solubility or miscibility (e.g., less than about 0.1 percent). The solid immiscibility of materials may be due to large differences in atomic size (e.g., 15% or more) and a high positive enthalpy of mixing into a solid solution arrangement. Similar atomic radii (e.g., less than about 13% difference), crystal structure, electronegativities, and similar valency may be required for (substitutional) solid solutions (in accordance with the Hume-Rothery rules).

For example, in embodiments where the metal layer 150 includes Ag, the conductive buffer layer 140 includes Ni and the conductive submount 130 includes Cu, the Ni-based conductive buffer layer 140 may have complete solid solubility with the Cu-based conductive submount. Complete solid solubility may occur when components have the same crystal structure, and the size factor is less than about 8%. As Ni may dissolve in Cu at all concentrations without a change in structure, the atom sizes may differ by about 2%, and the electronegativities and the crystal structures are the same, an Ni—Cu intermetallic compound 145 may be formed along the bonding interface 116 (the Ni—Cu bonding interface) between the Ni-based conductive buffer layer 140 and the Cu-based conductive submount 130.

In contrast, along the opposing bonding interface 112 (the Ag—Ni bonding interface), the Ni-based conductive buffer layer 140 and the Ag-based metal layer may have limited or no solubility (e.g., negligible miscibility) due to a difference in atomic size of about 14% or more and enthalpy of about +23 KJ/mol. It will be understood that complete immiscibility of solid phases in eutectic systems usually does not occur, for example, due to material impurities, contaminants, imperfect crystal structures, etc. Temperature, pressure and other parameters could also affect the (im)miscibility (smaller lattice vibrations at lower temperature so less space between the atoms).

In the comparative example shown in FIG. 9, a Cu—Ag intermetallic compound 855 is formed along the bonding interface 812 (the Cu—Ag bonding interface) between the Ag-based metal layer 850 and the Cu-based conductive submount 830. The Ag-based metal layer 850 and the Cu-based conductive submount 830 may have at least limited solid solubility (e.g., less than about 1% at room temperature), as the atomic size difference is 12%, Cu and Ag both have the FCC structure, and the electronegativities differ by about 0.4, with similar valency.

Referring again to FIGS. 4A and 4B, the conductive buffer layer 140 may have a thickness of about 0.1 microns to about 5 microns. For example, the thickness of the conductive buffer layer 140′, 140″ may be about 0.2 microns to about 1 micron. The conductive buffer layer 140′ of FIG. 4A may include metals such as Ni, Co, Mo, Cr, Ti, which are alloyed with different elements (e.g., vanadium (V), cobalt, (Co), or tungsten (W), such as NiV, NiCo, or NiW) to enhance its barrier capability and/or further balance interfacial properties (stress).

The conductive buffer layer 140″ of FIG. 4B may be provided as a multi-layer structure including a plurality of alternating sublayers 140a, 140b. Although two sublayers 140a, 140b are illustrated, it will be understood that three or more sublayers may be provided. For example, the conductive buffer layer 140″ may include one or more sublayers 140a, 140b (or alternating sublayers) of Ni, NiW, or NiV. The sublayers 140a, 140b of the conductive buffer layer 140″ may have respective thicknesses of about 0.1 microns to about 1 micron. The metal layer 150 may be Ag or Au, for example, with a thickness of about 1 micron. It will be understood that the thickness of the conductive buffer layer 140″ (and/or the respective thicknesses of the other conductive layers in the conductive layer stack 175) may also affect the value of the overall bonding strength n for the conductive layer stack 175.

FIG. 5 is a schematic cross-sectional view of an example semiconductor device package 500 including a conductive layer stack 175 with multiple buffer layers according to some embodiments of the present disclosure. FIG. 6 is an enlarged schematic cross-sectional view of portion VI-VI of the semiconductor device package 500 of FIG. 5.

In FIGS. 5 and 6, a semiconductor device package 500 includes a conductive submount 130, a transistor die 1000 on the conductive submount 130, and a conductive layer stack 175 between the transistor die 1000 and the conductive submount 130. The conductive submount 130 may provide a leadframe and/or one or more conductive leads (for example, an input lead and an output lead) of the semiconductor package. The conductive layer stack 175 includes a die attach material 170, at least one metal layer 150, 250, and at least one conductive buffer layer 140, 240. The transistor die 1000 (e.g., a SiC die) may include an input terminal coupled to the input lead (e.g., by a wire bond), and an output terminal coupled to the output lead (e.g., by the conductive layer stack 175). A mold structure 160 (e.g., epoxy, silicone, bismaleimide, or other mold compound) may be formed on the at least one metal layer 150, 250 opposite the conductive submount 130, similar to the package 100 of FIGS. 1 to 3.

As similarly shown in FIGS. 1 to 3, at least one metal layer of the conductive layer stack 175 may be or may include a first metal layer 150 that provides one or more die pads and/or one or more wire bond pads on the conductive submount 130. The first metal layer 150 may be formed on the conductive submount 130, for example, using a plating or other deposition process. At least one conductive buffer layer of the conductive layer stack 175 may be or may include a first conductive buffer layer 140 between the first metal layer 150 and the conductive submount 130.

As shown in FIGS. 5 and 6, at least one metal layer of the conductive layer stack 175 may be or may include a second metal layer 250, and at least one conductive buffer layer of the conductive layer stack 175 may be or may include a second conductive buffer layer 240 between the second metal layer 250 and a back surface or back side of the transistor die 1000. The second conductive buffer layer 240 and the second metal layer 250 may form part of a backside metallization 350 (also referred to as a back metal layer 350) of the transistor die 1000. The backside metallization 350 may include further conductive materials or layers (e.g., titanium (Ti)) in addition to the second conductive buffer layer 240 (e.g., nickel, cobalt, molybdenum, chromium) and the second metal layer 250 (e.g., gold, silver). For example, in some embodiments, the backside metallization 350 may be a Ti/Ni/Ag stack on the back surface of the transistor die 1000. That is, the conductive layer stack 175 between the transistor die 1000 and a conductive submount 130 of a semiconductor device package 500 may include a first conductive buffer layer 140 between a first metal layer 150 (which provides the die pad(s) and/or wire bond pad(s)) and the conductive submount 130, and/or a second conductive buffer layer 240 between a second metal layer 250 and the semiconductor material of the transistor die 1000 (where the second conductive buffer layer 240 and the second metal layer 250 may be included in the backside metallization 350 of the transistor die 1000).

Each metal layer 150, 250 of the conductive layer stack 175 has a lower bonding interface adjacent the conductive submount 130, and an upper bonding interface opposite the lower bonding interface. The materials and/or thicknesses of the conductive buffer layer(s) 140, 240 may be configured to reduce differences in interfacial stress at the opposing upper and lower bonding interfaces of the respective metal layer(s) 150, 250. For example, each metal layer 150, 250 may include or may be formed of a first material (e.g., noble metal or alloy thereof), and each conductive buffer layer 140, 240 may include or may be formed of a second material (e.g., nickel, cobalt, molybdenum, chromium, titanium, or alloys thereof) having limited or no solid solubility with respect to the first material, thereby reducing or preventing formation of intermetallic compounds 855 of the first material (having higher bonding strengths η2′) therebetween. As noted above, the thickness of the conductive buffer layer(s) 140, 240 (and/or the respective thicknesses of the metal layer(s) 150, 250, die attach material(s) 170, and/or other layers in the conductive layer stack 175) may also affect the value of the overall bonding strength n for the conductive layer stack 175. In some embodiments, the conductive buffer layer(s) 140, 240 may each have a thickness of about 0.1 microns to about 5 microns (e.g., about 0.2 microns to about 1 micron). That is, the materials and/or thicknesses of the respective layers of the conductive layer stack 175 may be configured to reduce differences the respective bonding strengths n at the various bonding interfaces between layers of dissimilar materials, which may in turn reduce differences in interfacial stress at the various bonding interfaces (including opposing upper and lower bonding interfaces of the respective metal layers 150, 250) of the conductive layer stack 175.

In particular, in the example of FIGS. 5 and 6, the materials and/or thicknesses of the first and second conductive buffer layers 140 and 240 are configured such that a first interfacial stress at a bonding interface 111 between the first metal layer 150 and the mold structure 160 is substantially similar to a second interfacial stress at a bonding interface 112 between the first metal layer 150 and the first conductive buffer layer 140 (i.e., η1≈η2). A third interfacial stress at a bonding interface 113 between the first metal layer 150 and the die attach material 170 is substantially similar to a fourth interfacial stress at a bonding interface 114 between the second metal layer 250 and the die attach material 170 (i.e., η3≈η4). A fifth interfacial stress at a bonding interface 115 between the second metal layer 250 and the second conductive buffer layer 240 is substantially similar to the second interfacial stress at the lower bonding interface 112 between the first metal layer 150 and the first conductive buffer layer 140 (i.e., η5≈η2). For example, the backside metallization 350 of the die 1000 and the conductive submount 130 may each include a respective Ni conductive buffer layer 140, 240 and a respective Ag metal layer 150, 250 such that that η3≈η4 and η2≈η5. More generally, embodiments of the present disclosure may thereby include combinations of thicknesses and materials of metal layers 150, 250 and conductive buffer layers 140, 240 that are configured to balance the adhesion strengths (and thus interfacial stresses) at the various interfaces 111, 112, 113, 114, 115 between layers of dissimilar materials throughout the conductive layer stack 175.

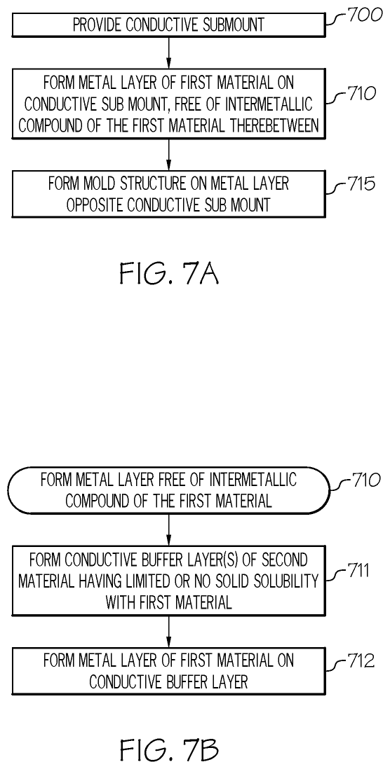

FIGS. 7A and 7B are flowcharts illustrating example operations for fabricating a semiconductor device package 100, 500 according to some embodiments of the present disclosure. As shown in FIG. 7A, in a method of fabricating a semiconductor device package 100, 500, a conductive submount 130 or lead is provided at block 700. As noted above, the conductive submount 130 or lead may be copper, copper alloys or other materials, such as iron-nickel alloys. At block 710, a metal layer 150, 250 of a first material is formed on the conductive submount 130. The metal layer 150, 250 may provide a wire bond pad, die pad, interconnect, or electrode. The first material may be a noble metal, such as Ag, Au, or alloys thereof (e.g., AgCo, AgW, AgMo). The metal layer 150, 250 may be deposited at block 710 using various methods, including (but not limited to) electroplating, electroless plating, sputtering, and thermal evaporation. The first material of the metal layer 150, 250 may have a relatively high solid solubility with respect to the material of the conductive submount 130, but may be formed on the conductive submount 130 at block 710 free of an intermetallic compound 855 of the first material therebetween.

For example, as shown in FIG. 7B, the operations of block 710 may include forming one or more conductive buffer layers 140, 240 of a second material at block 711, and forming the metal layer 150, 250 of the first material on the conductive buffer layer 140, 240 at block 712. The second material of the conductive buffer layer 140, 240 has limited or no solid solubility with respect to the first material of the metal layer 150, 250. For example, as noted above, while the first material may be a noble metal or alloy thereof, the second material may include at least one of nickel, cobalt, molybdenum, chromium, titanium, or alloys thereof, such that an intermetallic compound 855 of the first material is not formed at the bonding interface 112, 115 between the metal layer 150, 250 and the conductive buffer layer 140, 240. In some embodiments, the second material may have a high solid solubility with respect to the material of the conductive submount 130, such that an intermetallic compound 145 of the second material may be formed between the conductive buffer layer 140 and the conductive submount 130, as shown in FIG. 2.

In some embodiments, at block 711, a thin layer (e.g., with a thickness of about 0.8 μm) of Ni is deposited as a conductive buffer layer 140 on a Cu leadframe, and an Ag metal layer 150 (e.g., with a thickness of about 1 μm) is deposited on the Ni conductive buffer layer 140 at block 712. Ni may not form an intermetallic compound with Ag, and may also have limited to no solid solubility with Ag at temperatures of less than 960° C. The conductive buffer layer 140 may also include metals other than Ni, for example, Co, Mo, Cr, Ti, etc., or may be alloyed with different elements (e.g., vanadium, cobalt, or tungsten, such as NiV, NiCo, or NiW) to enhance its barrier capability and or further tune the interfacial properties (e.g., stress). As discussed above with reference to FIG. 4B, the conductive buffer layer 140 may also be implemented as a multi-layer structure 140″ including sublayers 140a, 140b of different materials to further engineer the overall stress at the respective bonding interfaces, such as the bonding interface 111 between the metal layer 150 and the mold structure 160 (e.g. EMC). For example, the conductive buffer layer 140 may include alternating thin buffer layers (e.g., each about 0.1 um to about 1 um-thick) of Ni and NiW, or of Ni and Co. Ni—, Co—, or Mo-based conductive buffer layers 140, 240 may be particularly effective in providing substantially similar bonding strengths at opposing upper and lower bonding surfaces of an Ag-based metal layer 150, 250 on a Cu-based conductive submount 130.

In some embodiments, at block 711, a thin layer of Ni is deposited as a conductive buffer layer 240 on the backside of a SiC transistor die 1000, and an Ag metal layer 250 is deposited on the Ni conductive buffer layer 240 at block 712. The SiC die may be attached to an Ag die attach pad on a Cu leadframe by a die attach material 170. As such, a SiC-based transistor die 1000 may be fabricated with a backside metallization 350 that is configured to provide substantially similar bonding strengths (and thus, substantially similar interfacial stresses) at opposing upper and lower surfaces of the Ag-based metal layer 250 thereof.

Referring again to FIG. 7A, a mold structure 160 is formed on the metal layer 150 opposite the conductive submount 130 at block 715. As such, the metal layer 150 may include a lower bonding interface 112 with the buffer layer, and an upper bonding interface 111 with the mold structure 160 opposite the lower bonding interface 112.

In embodiments of the present disclosure, due to the formation of the conductive buffer layer 140 at block 711, a bonding strength η2 at a lower bonding interface 112 of a metal layer 150 is less (i.e., weaker) than a bonding strength η2′of a direct bonding interface between the metal layer 150 and a conductive submount 130. The reduction in bonding strength at the lower bonding interface 112 can reduce or prevent an imbalance or unevenness of the bonding strengths η1 and η2 at the upper and lower bonding interfaces 111, 112 of the metal layer 150, respectively, such that a first interfacial stress at the upper bonding interface 111 may be substantially similar to a second interfacial stress at the lower bonding interface 112. As such, delamination between the mold structure 160 and the metal layer 150 may be reduced or prevented.

In particular embodiments, the conductive buffer layer 140, 240 includes a metal or metal alloy (e.g., having a thickness of about 0.2 μm to 1 μm) that has no or limited solid solubility with the metal of the metal layer 150, 250 (e.g. having a comparatively greater thickness of about 0.5 μm to about 1.5 μm), and does not form an intermetallic compound with metal layer 150, 250. The metal layer 150, 250 may include (but is not limited to) noble metals, such as Ag and Au. The metal layer 150 may provide die attach pads, wire-bonding pads, interconnects, or electrodes for the semiconductor device package 100, 500. The metal layer 150, 250 can be deposited on the conductive submount 130, on the backside of the semiconductor die, and/or on other substrates such as DBC, AMB, and ceramics, with the conductive buffer layer 140, 240 therebetween. The conductive submount 130 may be a leadframe or other conductive lead, and may include (but is not limited to) copper, copper alloys (e.g. C194, C7025, C151, TAMAC4, etc.) or other materials such as Alloy 42 (Fe-42Ni). The molding structure may include a molding compound such as (but not limited to) epoxy, silicon, bismaleimide in different formulations such as single, binary, or ternary resins (Bismaleimide/Phenolic/Epoxy) with or without fillers.

The present disclosure has primarily been discussed above with respect to semiconductor device packages for power semiconductor devices including silicon carbide-based transistor dies. It will be appreciated, however, that silicon carbide is used herein as an example and that the devices discussed herein may be formed in any appropriate wide bandgap semiconductor material system. As an example, gallium nitride based semiconductor materials (e.g., gallium nitride, aluminum gallium nitride, etc.) may be used instead of silicon carbide in any of the embodiments described above. More generally, while discussed with reference to silicon carbide devices, embodiments of the present invention are not so limited, and may have applicability to devices formed using other wide bandgap semiconductor materials, for example, gallium nitride, zinc selenide, or any other II-VI or III-V wide bandgap compound semiconductor materials.

Embodiments of the present invention have been described above with reference to the accompanying drawings, in which embodiments of the invention are shown. It will be appreciated, however, that this invention may, however, be embodied in many different forms and should not be construed as limited to the embodiments set forth above. Rather, these embodiments are provided so that this disclosure will be thorough and complete, and will fully convey the scope of the invention to those skilled in the art. Like numbers refer to like elements throughout.

It will be understood that, although the terms first, second, etc. are used throughout this specification to describe various elements, these elements should not be limited by these terms. These terms are only used to distinguish one element from another. For example, a first element could be termed a second element, and, similarly, a second element could be termed a first element, without departing from the scope of the present invention. The term “and/or” includes any and all combinations of one or more of the associated listed items.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “top” or “bottom” may be used herein to describe a relationship of one element, layer or region to another element, layer or region as illustrated in the figures. It will be understood that these terms are intended to encompass different orientations of the device in addition to the orientation depicted in the figures.

Embodiments of the invention are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Embodiments of the invention are also described with reference to fabrication operations, for example, with reference to flowchart diagrams. It will be appreciated that the steps shown in the fabrication operations need not be performed in the order shown.

In the drawings and specification, there have been disclosed typical embodiments of the invention and, although specific terms are employed, they are used in a generic and descriptive sense only and not for purposes of limitation, the scope of the invention being set forth in the following claims.

1. A semiconductor device package, comprising:
a conductive submount;
a metal layer comprising a first material on the conductive submount; and
a conductive buffer layer comprising a second material on the metal layer,
wherein the second material of the conductive buffer layer has limited or no solid solubility with respect to the first material of the metal layer.

2. The semiconductor device package of claim 1, wherein the conductive buffer layer is between the metal layer and the conductive submount, and wherein the semiconductor device package is free of an intermetallic compound comprising the first material between the metal layer and the conductive submount.

3. The semiconductor device package of claim 2, further comprising:
an intermetallic compound comprising the second material between the conductive buffer layer and the conductive submount.

4. The semiconductor device package of claim 2, wherein the first material comprises a noble metal or alloy thereof, and the second material comprises at least one of nickel, cobalt, molybdenum, chromium, titanium, or alloys thereof.

5. The semiconductor device package of claim 1, wherein the metal layer comprises a lower bonding interface with the conductive buffer layer and an upper bonding interface opposite the lower bonding interface,
wherein a first interfacial stress at the upper bonding interface is substantially similar to a second interfacial stress at the lower bonding interface.

6. The semiconductor device package of claim 5, wherein a bonding strength at the lower bonding interface is less than a bonding strength of a direct bonding interface between the metal layer and the conductive submount.

7. The semiconductor device package of claim 5, further comprising:
a mold structure on the metal layer opposite the conductive submount,
wherein the upper bonding interface is between the metal layer and the mold structure.

8. The semiconductor device package of claim 7, wherein the mold structure comprises at least one of epoxy, silicone, or bismaleimide.

9. The semiconductor device package of claim 7, wherein the metal layer is a first metal layer, and further comprising:
a die attach material on the first metal layer opposite the conductive submount; and
a second metal layer on the die attach material,
wherein a third interfacial stress at a bonding interface between the first metal layer and the die attach material is substantially similar to a fourth interfacial stress at a bonding interface between the second metal layer and the die attach material.

10. The semiconductor device package of claim 8, wherein the conductive buffer layer is a first conductive buffer layer, and further comprising:
a transistor die on the die attach material opposite the first metal layer; and
a second conductive buffer layer between the transistor die and the second metal layer,
wherein the second conductive buffer layer and the second metal layer comprise a back metal layer of the transistor die, and
wherein a fifth interfacial stress at a bonding interface between the second metal layer and the second conductive buffer layer is substantially similar to the second interfacial stress at the lower bonding interface between the first metal layer and the first conductive buffer.

11. The semiconductor device package of claim 1, wherein the conductive submount comprises copper, iron, or alloys thereof.

12. The semiconductor device package of claim 1, wherein the conductive buffer layer has a thickness of about 0.1 microns to about 5 microns, or about 0.2 microns to about 1 micron.

13. The semiconductor device package of claim 1, wherein the conductive buffer layer comprises a multi-layer structure including a plurality of alternating sublayers having respective thicknesses of about 0.1 microns to about 1 micron.

14. A semiconductor device package, comprising:
a conductive submount; and
a metal layer comprising a first material on the conductive submount,
wherein the semiconductor device package is free of an intermetallic compound comprising the first material between the metal layer and the conductive submount.

15. The semiconductor device package of claim 14, further comprising:
a conductive buffer layer comprising a second material between the conductive submount and the metal layer,
wherein the second material has limited or no solid solubility with respect to the first material.

16. The semiconductor device package of claim 15, further comprising:
an intermetallic compound comprising the second material between the conductive buffer layer and the conductive submount.

17. The semiconductor device package of claim 15, wherein the first material comprises a noble metal or alloy thereof, and the second material comprises at least one of nickel, cobalt, molybdenum, chromium, titanium, or alloys thereof.

18. The semiconductor device package of claim 14, wherein the metal layer comprises a lower bonding interface adjacent the conductive submount and an upper bonding interface opposite the lower bonding interface,
wherein a first interfacial stress at the upper bonding interface is substantially similar to a second interfacial stress at the lower bonding interface.

19. The semiconductor device package of claim 18, further comprising:
a mold structure on the metal layer opposite the conductive submount,
wherein the upper bonding interface is between the metal layer and the mold structure.

20. The semiconductor device package of claim 18, wherein a bonding strength at the lower bonding interface is less than a bonding strength of a direct bonding interface between the metal layer and the conductive submount.

21. A semiconductor device package, comprising:
a conductive submount; and
a conductive layer stack comprising a metal layer on the conductive submount, the metal layer comprising a lower bonding interface adjacent the conductive submount and an upper bonding interface opposite the lower bonding interface,
wherein a first interfacial stress at the upper bonding interface is substantially similar to a second interfacial stress at the lower bonding interface.

22.-29. (canceled)

30. A semiconductor device package, comprising:
a conductive submount; and
a metal layer on the conductive submount, the metal layer comprising a lower bonding interface adjacent the conductive submount,
wherein a bonding strength at the lower bonding interface is less than a bonding strength of a direct bonding interface between the metal layer and the conductive submount.

31.-35. (canceled)

36. A method of fabricating a semiconductor device package, the method comprising:
providing a conductive submount; and
forming a metal layer comprising a first material on the conductive submount and free of an intermetallic compound comprising the first material between the metal layer and the conductive submount.

37.-44. (canceled)

45. A semiconductor device package, comprising:
a conductive submount;
a transistor die on the conductive submount; and
a conductive layer stack between the transistor die and the conductive submount, the conductive layer stack comprising a die attach material, at least one metal layer comprising a first material, and at least one conductive buffer layer comprising a second material having limited or no solid solubility with respect to the first material.

46.-50. (canceled)
